(19) United States
(12) Patent Application Publication
(10) Pub. No.: US 2005/0286592 A1
(43) Pub. Date: Dec. 29, 2005

(54) Semiconductor laser array device

(75) Inventors: Naoyuki Shimada, Tokyo (JP); Kimio Shigihara, Tokyo (JP); Kazushige Kawasaki, Tokyo (JP); Kimitaka Shibata, Tokyo (JP); Tetsuya Yagi, Tokyo (JP); Kenichi Ono, Tokyo (JP); Hideki Haneda, Tokyo (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Mitsubishi Denki Kabushiki Kaisha, Tokyo (JP)

(21) Appl. No.: 11/078,498

(22) Filed: Mar. 14, 2005

(30) Foreign Application Priority Data
Jun. 24, 2004 (JP) P 2004-186265

(51) Int. Cl. H01S 5/00; H01S 3/04

(52) U.S. Cl. 372/50.12; 372/50.1; 372/36

(57) ABSTRACT

A semiconductor laser array device for outputting a higher power includes: a plurality of semiconductor laser chips, arranged in a predetermined pitch; a submount for mounting each semiconductor laser chip; and a heat sink for dissipating heat from the semiconductor laser chip through the submount; wherein a distance S between the centers of the chips and a thickness T of the submount satisfy the following inequality: 2×T≦S≦10×T, whereby improving efficiency of heat dissipation with a good process yield.

### BACKGROUND OF THE INVENTION

1. Field of the Invention

The present invention relates to a semiconductor laser array device for outputting a higher power.

2. Description of the Related Art

In a conventional approach using a plurality of semiconductor laser devices for outputting a higher power, a laser diode bar (LD bar) is provided with a plurality of emission regions on a single semiconductor bar, and die-bonded on a submount or a heat sink.

The related prior arts are listed as follows: Japanese Patent Unexamined Publications (kokai) JP-A-2003-209313 (FIGS. 2 and 4), and JP-A-2003-158332 (FIG. 1).

The LD bar has emission regions with such a small interval that heat which is generated in each emission region is transferred to the submount or the heat sink under a relatively high thermal resistance, therefore the heat hardly dissipate with high efficiency. Since rise in temperature of the emission region may degrade durability and characteristics, there is a certain ceiling on increasing the output power.

### SUMMARY OF THE INVENTION

An object of the present invention is to provide a semiconductor laser array device for outputting a higher power by improving efficiency of heat dissipation with a good process yield.

To achieve the above-mentioned object, a semiconductor laser array device according to the present invention, includes: a plurality of semiconductor laser chips, arranged in a predetermined pitch; a submount for mounting each semiconductor laser chip; and a heat sink for dissipating heat from the semiconductor laser chip through the submount; wherein a distance S between the centers of the chips and a thickness T of the submount satisfy the following inequality: 2×T≦S≦10×T.

In the present invention, an oscillation wavelength of each semiconductor laser chip is preferably in a range of the center wavelength ±4 nm.

In the present invention, an oscillation threshold of each semiconductor laser chip is preferably in a range of the standard oscillation threshold ±5%.

In the present invention, an external differential quantum efficiency of each semiconductor laser chip is preferably in a range of the standard external differential quantum efficiency ±5%.

In the present invention, an operating current of each semiconductor laser chip is preferably in a range of the standard operating current ±5%.

According to the present invention, a plurality of semiconductor laser chips are so arranged on the submount that the distance S between the centers of the chips and the thickness T of the submount satisfy the following inequality: 2×T≦S≦10×T, thereby downsizing the whole array and attaining higher efficiency of heat dissipation. Consequently, degradation of durability and characteristics can be prevented with a good process yield and a higher output power.

### BRIEF DESCRIPTION OF THE DRAWINGS

FIG. 1 is a partial perspective view showing the first embodiment according to the present invention.

### DETAILED DESCRIPTION OF THE PREFERRED EMBODIMENTS

This application is based on an application No. 2004-186265 filed on Jun. 24, 2004 in Japan, the disclosure of which is incorporated herein by reference.

Hereinafter, preferred embodiments will be described with reference to drawings.

### Embodiment 1

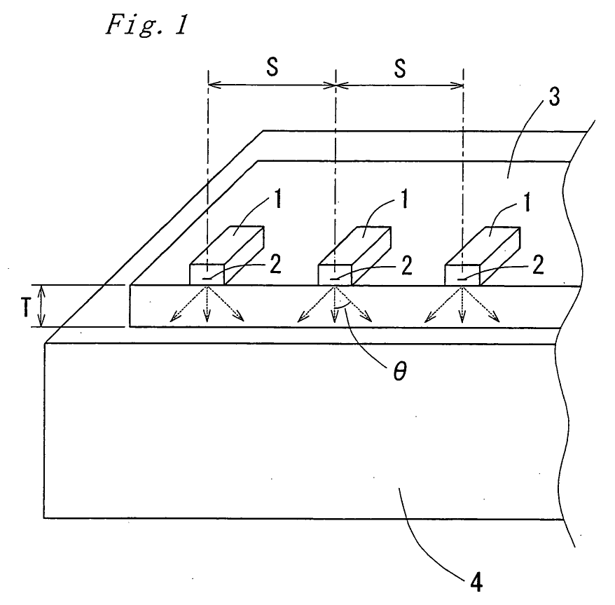

FIG. 1 is a partial perspective view showing the first embodiment according to the present invention. A semiconductor laser array device includes a plurality of semiconductor laser chips 1, a submount 3, and a heat sink 4.

The semiconductor laser chip 1 has an active layer, and a pair of cladding layers located on both sides of the active layer, in which light generated from the active layer by carrier injection passes through an emission region 2 in an end face for emitting the light exteriorly. On the upper surface of the semiconductor laser chip 1 formed is a first electrode, onto which a lead wire (not shown) is connected. On the lower surface of the semiconductor laser chip 1 formed is a second electrode, to which the submount 3 is electrically, thermally and mechanically connected by die bonding or the like.

The submount 3 is formed of an electrically and thermally conductive metal or another material having a good thermal conductivity, such as CuW (copper-tungsten), AlN (aluminum nitride), SiC (silicon carbide), or Si (silicon), and generally in the shape of plate.

The heat sink 4 is a member having a large thermal capacity and formed of a metal with a good thermal conductivity, such as Cu (copper) or Ag (silver). Heat received by the heat sink 4 is further dissipated to an atmosphere, an external chassis or cooling water. The submount 3 and the heat sink 4 are electrically, thermally and mechanically connected to each other using a solder or another electrically and thermally conductive adhesive so as to ensure a good thermal conductivity.

Part of heat generated during energizing the semiconductor laser chip 1 is dissipated to a surrounding atmosphere and major part of the heat is transferred through the submount 3 to the heat sink 4. In this case, as shown by a dotted line in FIG. 1, a heat conducting region is extended from the lower surface of the semiconductor laser chip 1 in a range of divergent angle θ with respect to the thickness direction of the heat sink 4. This divergent angle θ of the heat conducting region is typically 45 degree in terms of half angle.

In case a distance between the centers of the semiconductor laser chips 1 is referred to as S and a thickness of the submount 3 is referred to as T, the smaller the thickness T becomes, the smaller the thermal resistance of the submount 3 becomes. In addition, as the distance S between the chip centers is designed smaller, the heat conducting regions of adjacent chips are gradually overlapped to each other, thereby reducing the efficiency of heat dissipation.

In this embodiment, chip arrangement is designed so as to satisfy an optimal condition: 2×T≦S≦10×T, on relation of the distance S between the chip centers and the thickness T of the submount 3. In a case of the distance S between the chip centers smaller than 2T, the heat conducting regions of adjacent chips are overlapped to each other in the vicinity of the back face of the submount 3, with no good result. Meanwhile, In another case of the distance S between the chip centers larger than 10T, the larger pitch between chips causes the whole length of the array to become larger than necessary. Accordingly, satisfying the inequality: 2×T≦S≦10×T can downsize the whole array and attain higher efficiency of heat dissipation.

### Embodiment 2

In this embodiment, the semiconductor laser chips 1 with smaller variations in oscillation wavelength are mounted in such a configuration as shown in FIG. 1.

In general, for product specifications of a semiconductor laser array device, a center wavelength λc and a full width at half maximum (FWHM) of the emission spectrum are specified. Therefore, when a plurality of semiconductor laser chips 1 are mounted, the oscillation wavelength of each chip is required to be screened.

Accordingly, it is preferable that the semiconductor laser chip 1, whose oscillation wavelength is in a range of the center wavelength λc ±4 nm, is screened to be mounted on the submount 3, thereby narrowing the emission spectrum bandwidth of the whole array and realizing a more monochromatic semiconductor laser array device.

### Embodiment 3

In this embodiment, the semiconductor laser chips 1 with smaller variations in oscillation threshold, external differential quantum efficiency and operating current are mounted in such a configuration as shown in FIG. 1.

In general, for product specifications of a semiconductor laser array device, a standard oscillation threshold Ith and the allowable range thereof, a standard is external differential quantum efficiency rex and the allowable range thereof, and a standard operating current Iop and the allowable range thereof, etc. are specified.

The oscillation threshold is defined as a current value at a point where a linear line during laser oscillation intersects the horizontal axis (current) in the current-optical power (I-P) characteristics of a semiconductor laser. The external differential quantum efficiency is defined as a slope ΔP/ΔI of the linear line during laser oscillation in the current-optical power characteristics. The operating current is defined as a current value at a predetermined optical power.

Therefore, when a plurality of semiconductor laser chips 1 are mounted, the oscillation threshold, the external differential quantum efficiency and the operating current of each chip are required to be screened.

Accordingly, it is preferable that the semiconductor laser chip 1, whose oscillation threshold is in a range of the standard oscillation threshold Ith ±5%, is screened to be mounted on the submount 3, thereby suppressing the variation in oscillation threshold of the whole array.

Further, it is preferable that the semiconductor laser chip 1, whose external differential quantum efficiency is in a range of the standard external differential quantum efficiency ηex ±5%, is screened to be mounted on the submount 3, thereby suppressing the variation in differential quantum efficiency of the whole array.

Furthermore, it is preferable that the semiconductor laser chip 1, whose operating current is in a range of the standard operating current Iop ±5%, is screened to be mounted on the submount 3, thereby suppressing the variation in operating current of the whole array.

### Embodiment 4

In this embodiment, since the semiconductor laser chips 1 are discretely mounted in such a configuration as shown in FIG. 1, a chip which has been approved as a fair product by preliminary inspection of the specifications, including oscillation wavelength, oscillation threshold, external differential quantum efficiency and operating current, can be screened before mounting each chip.

For example, on the assumption that a defective chip is produced at a rate of one per fifty, i.e., a defective fraction of 2%, a case of manufacturing a laser array composed of 10 semiconductor lasers will be discussed below. In the case of 10 emission regions formed on a LD bar as described in the conventional art, the expected value of the number of the arrays when producing them by using 1,000 laser devices is 82 (=0.98¹⁰×1,000). Namely, when manufacturing 100 laser arrays, 18 arrays out of them will be defective.

Meanwhile, in case of discretely mounting a single chip according to the present invention, the expected value is 98 (=0.98×1,000/10). Namely, when manufacturing 100 laser arrays, only 2 arrays out of them will be defective. Therefore, it can be seen that the laser array according to the present invention is extremely superior in process yield to the conventional LD bar.

Although the present invention has been fully described in connection with the preferred embodiments thereof and the accompanying drawings, it is to be noted that various changes and modifications are apparent to those skilled in the art. Such changes and modifications are to be understood as included within the scope of the present invention as defined by the appended claims unless they depart therefrom.

1. A semiconductor laser array device comprising:
a plurality of semiconductor laser chips, arranged in a predetermined pitch;
a submount for mounting each semiconductor laser chip; and
a heat sink for dissipating heat from the semiconductor laser chip through the submount;
wherein a distance S between the centers of the chips and a thickness T of the submount satisfy the following inequality: 2×T≦S≦10×T.

2. The semiconductor laser array device according to claim 1, wherein an oscillation wavelength of each semiconductor laser chip is in a range of the center wavelength ±4 nm.

3. The semiconductor laser array device according to claim 1, wherein an oscillation threshold of each semiconductor laser chip is in a range of the standard oscillation threshold ±5%.

4. The semiconductor laser array device according to claim 1, wherein an external differential quantum efficiency of each semiconductor laser chip is in a range of the standard external differential quantum efficiency ±5%.

5. The semiconductor laser array device according to claim 1, wherein an operating current of each semiconductor laser chip is in a range of the standard operating current ±5%.
